(19) United States
(12) Patent Application Publication
(10) Pub. No.: US 2009/0261341 A1
(43) Pub. Date: Oct. 22, 2009

(54) ORGANIC LIGHT EMITTING DISPLAY AND METHOD OF MANUFACTURING THE SAME

(76) Inventors: Jung-Mi Choi, Seoul (KR); Won-Hoe Koo, Suwon-si (KR); Hoon Kim, Hwaseong-si (KR)

Correspondence Address: Haynes and Boone, LLP;IP Section, 2323 Victory Avenue, SUITE 700, Dallas, TX, 75219, US

(21) Appl. No.: 12/368,134

(22) Filed: Feb. 9, 2009

(30) Foreign Application Priority Data
Apr. 21, 2008 (KR) 2008-36768

(51) Int. Cl. H01L 33/00

(52) U.S. Cl. 257/72; 438/26; 257/E33.003

(57) ABSTRACT

An organic light emitting display includes a pixel part adapted to generate a light and a metal oxide layer. The metal oxide layer is formed by oxidation of a metal layer combined with oxygen of gas or humidity in an inner space of the organic light emitting display. Accordingly, gas or humidity in the organic light emitting display is removed by the oxidation of the metal oxide layer to thereby inhibit deterioration in a light emitting function of the pixel part.

### CROSS-REFERENCE TO RELATED APPLICATIONS

This application claims priority to and benefit of Korean Patent Application No. 2008-36768, filed on Apr. 21, 2008, the contents of which are herein incorporated by reference in its entirety.

### BACKGROUND

1. Technical Field

The present invention relates to an organic light emitting display and a method of manufacturing the organic light emitting display, and more particularly, to an organic light emitting display capable of improving reliability thereof and a method of manufacturing the organic light emitting display.

2. Related Art

Among various flat panel displays (FPD), an organic light emitting display (OLED) is a self-emissive type device having improved characteristics, such as wide viewing angle, rapid response speed, high contrast ratio, and so forth.

In general, the OLED includes a substrate, an anode arranged on the substrate, an emission layer arranged on the anode, and a cathode arranged on the emission layer. In the OLED having such a structure, when a voltage is applied to the anode and the cathode, holes and electrons are injected into the emission layer, and the holes and the electrons injected into the emission layer are recombined in the emission layer to generate an exciton. When the exciton is transferred from an excited state to a ground state, energy is generated, and the emission layer emits a light using the energy.

If the emission layer reacts with humidity or gas, a light emitting function of the emission layer is deteriorated due to the chemical reaction. As a result, the reliability of the OLED decreases.

### SUMMARY

An exemplary embodiment of the present disclosure provides an organic light emitting display having improved reliability. Another exemplary embodiment of the present disclosure provides a method of manufacturing the organic light emitting display.

In an exemplary embodiment of the present disclosure, a method of manufacturing an organic light emitting display is provided as follows. A pixel part that generates a light is formed on a first substrate, and a metal layer is formed on a second substrate. A coupling member is formed on the first substrate or on the second substrate, and the first substrate and the second substrate are coupled using the coupling member. The metal layer is combined with oxygen and humidity near the pixel part and is oxidized. Thus, the oxygen and humidity may be removed as the metal layer is oxidized, thereby improving reliability and lifecycle of the organic light emitting display.

In another exemplary embodiment of the present disclosure, an organic light emitting display includes a first substrate, a pixel part arranged on the first substrate to generate a light, a second substrate facing the first substrate, a coupling member interposed between the first substrate and the second substrate to couple the first substrate and the second substrate, and a metal oxide layer arranged on the second substrate. The metal oxide layer is formed by oxidation of a metal layer combined with oxygen or humidity near the pixel part. Thus, oxygen or humidity near the pixel part is removed by oxidation of the metal oxide layer, thereby improving reliability and lifecycle of the organic light emitting display.

Accordingly, the metal layer is combined with humidity and gas near the pixel part and is oxidized, so that the oxygen near the pixel part may be removed. Therefore, the light emitting function of the pixel part may be prevented from being deteriorated by humidity and gas, thereby improving reliability and lifecycle of the organic light emitting display.

### BRIEF DESCRIPTION OF THE DRAWINGS

The above and other advantages of the present disclosure will become readily apparent by reference to the following detailed description when considered in conjunction with the accompanying drawings wherein:

FIG. 1 is a sectional view showing an exemplary embodiment of an organic light emitting display according to the present disclosure;

FIG. 2 is an enlarged sectional view showing a display area of an organic light emitting display of FIG. 1; and

FIGS. 3 to 8 are views illustrating an exemplary embodiment of a manufacturing method of an organic light emitting display of FIG. 1.

### DESCRIPTION OF EMBODIMENTS

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the disclosure. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present disclosure will be described in detail with reference to the accompanying drawings.

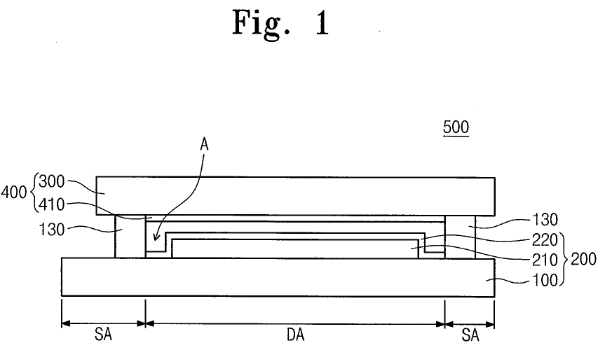

FIG. 1 is a sectional view showing an exemplary embodiment of an organic light emitting display according to the present disclosure. Referring to FIG. 1, an organic light emitting display 500 includes an array substrate 200, a cover substrate 400 facing the array substrate 200, and a coupling member 130 that is interposed between the array substrate 200 and the cover substrate 400 to couple the array substrate 200 and the cover substrate 400 with each other.

The array substrate 200, in one embodiment, includes a first base substrate 100, a pixel part 210 arranged on the first base substrate 100, and a protective layer 220 arranged on the pixel part 210. The first base substrate 100, in one embodiment, may include a transparent glass substrate or a transparent plastic substrate, and the first base substrate 100 includes a display area DA and a peripheral area SA surrounding the display area DA.

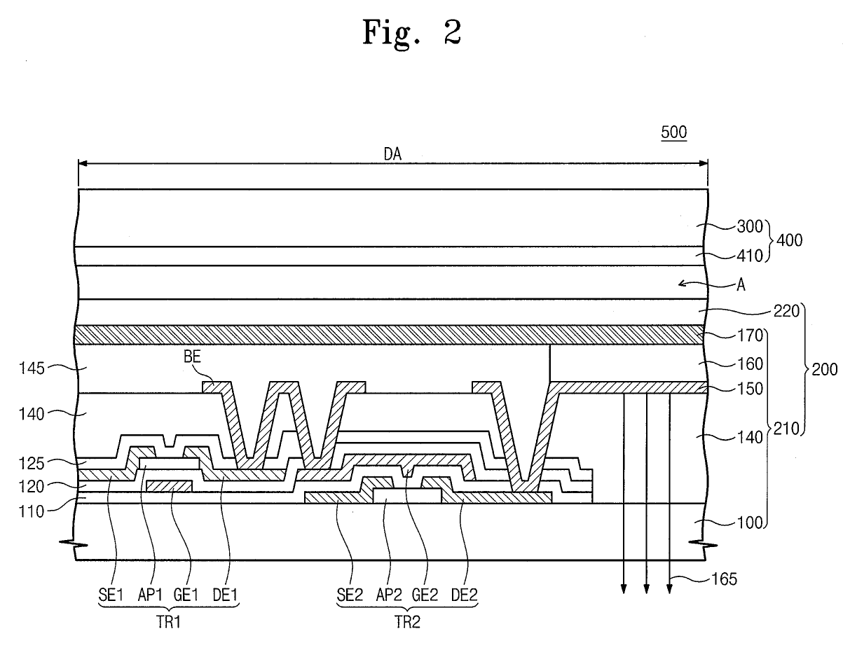

The pixel part 210, in one embodiment, is formed in the display area DA to generate a light. The pixel part 210 includes a plurality of pixels each of which includes an organic light emitting layer 160 (shown in FIG. 2), a first thin film transistor TR1 (shown in FIG. 2), and a second thin film transistor TR2 (shown in FIG. 2). The pixel part 210 will be further described in detail with reference to FIG. 2.

The coupling member 130, in one embodiment, is interposed between the array substrate 200 and the cover substrate 400 corresponding to the peripheral area SA to couple the array substrate 200 with the cover substrate 400. The coupling member 130 includes a frit made of glass, and the coupling member 130 is formed by melting the frit glass using heat and hardening the melted frit glass.

In various implementations, the coupling member 130 that couples the array substrate 200 with the cover substrate 400 may also prevent humidity or gas from being absorbed into the organic light emitting display 500. In the present exemplary embodiment, the coupling member 130 has low humidity permeability and low oxygen permeability because the coupling member 130 is formed by melting and hardening the frit glass. Thus, humidity or oxygen provided from an exterior to the pixel part 210 may be blocked by the coupling member 130, thereby preventing a light emitting function of the pixel part 210 from being deteriorated due to the humidity or oxygen.

The cover substrate 400, in one embodiment, includes a second base substrate 300 and a metal oxide layer 410 arranged on the second base substrate 300. The second base substrate 300 may include a transparent glass substrate or a transparent plastic substrate, and the metal oxide layer 410 is arranged on the second base substrate 300 corresponding to the display area DA.

The metal oxide layer 410, in one embodiment, includes an oxide formed by oxidation of a metal as titanium dioxide (TiO2). In one implementation, the metal oxide layer 410 is formed by oxidation of the metal combining with oxygen contained in an inner space (A) of the organic light emitting display 500, which is defined by the array substrate 200, the cover substrate 400, and the coupling member 130, so that the metal oxide layer 410 is formed. In addition, the metal may be oxidized by combining with oxygen from gas or humidity that is generated during a manufacturing process of the organic light emitting display 500. As a result, the gas and humidity containing oxygen may be removed by the oxidation of the metal oxide layer 410. The metal oxide layer 410 formed by the oxidation of the metal absorbs the humidity, so that the humidity near the pixel part 210 may be removed. In one aspect, according to a degree of oxidization of the metal, the metal oxide layer 410 may be provided with the metal that is not oxidized, or the metal may be completely oxidized.

The protective layer 220 is arranged on the pixel part 210. The protective layer 220 may include an epoxy resin, or the protective layer 220 may include a silicon nitride layer or a silicon oxide layer. The protective layer 220 covers an upper portion and a side portion of the pixel part 220, so that the protective layer 220 may prevent humidity or gas contained in the inner space (A) from being absorbed into the pixel part 210.

FIG. 2 is an enlarged sectional view showing a display area of the organic light emitting display of FIG. 1. Referring to FIG. 2, the array substrate 200 includes the first base substrate 100 and the pixel part 210 that is arranged on the first base substrate 100, and the pixel part 210 includes the first and second thin film transistors TR1 and TR2, the organic light emitting layer 160, a first electrode 150, and a second electrode 170. The first thin film transistor TR1 includes a first gate electrode GE1, a first source electrode SE1, a first drain electrode DE1, and a first active pattern AP1. Although not shown in FIG. 2, a gate line (not shown) and a data line (not shown) are formed on the first base substrate 100, and the first gate electrode GE1 is branched from the gate line, and the first source electrode SE1 is branched from the data line.

In one implementation, the first thin film transistor TR1 is turned on in response to a gate signal that is transmitted through the gate line and the first gate electrode GE1. When the first thin film transistor TR1 is turned on, the first active pattern AP1 is activated and thus a data signal transmitted through the data line and the first source electrode SE1 is applied to the first drain electrode DE1 through the first active pattern AP1.

The second thin film transistor TR2, in one embodiment, includes a second gate electrode GE2, a second source electrode SE2, a second drain electrode DE2, and a second active pattern AP2. Although not shown in FIG. 2, a bias line (not shown) that provides a source voltage to the organic light emitting layer 160 is formed on the first base substrate 100, and the second source electrode SE2 is branched from the bias line.

The second gate electrode GE2, in one embodiment, is electrically connected to the first drain electrode DE1 by a bridge electrode BE. Thus, the second thin film transistor TR2 may be turned on in response to the data signal that is provided through the first drain electrode DE1. When the second thin film transistor TR2 is turned on, the second active pattern AP2 is activated and thus a driving voltage transmitted through the bias line and the second source electrode SE2 is applied to the second drain electrode DE2 through the second active pattern AP2.

In one implementation, the array substrate 200 includes a plurality of insulating layers. As such, the array substrate 200 includes a first insulating layer 110 interposed between the first base substrate 100 and the first gate electrode GE1, a second insulating layer 120 interposed between the first active pattern AP1 and the first gate electrode GE1, a third insulating layer 125 arranged on the first source electrode SE1 and the first drain electrode DE1, a fourth insulating layer 140 arranged on the third insulating layer 125, and a fifth insulating layer 145 arranged on the fourth insulating layer 140.

The first electrode 150, in one embodiment, is electrically connected to the second drain electrode DE2. The organic light emitting layer 160 that makes contact with the first electrode 150 is arranged on the first electrode 150. A second electrode 170 that makes contact with the organic light emitting layer 160 is arranged on the organic light emitting layer 160.

In this exemplary embodiment of the present disclosure, the first electrode 150 may include a transparent conductive layer such as indium tin oxide or indium zinc oxide, and the second electrode 170 may include a metal material. Therefore, when a voltage is applied to the first electrode 150 and the second electrode 170, the organic light emitting layer 160 generates a light 165, the light 165 is reflected from a surface of the second electrode 170 and exits to an exterior through the first base substrate 100.

The protective layer 220, in one embodiment, is arranged on the pixel part 210. As described in FIG. 1, the protective layer 220 is formed at an uppermost position of the array substrate 200 to cover the pixel part 210.

The cover substrate 400, in one embodiment, includes the second base substrate 300 and the metal oxide layer 410 arranged on the second base substrate 300. The metal oxide layer 410 faces the pixel part 210 while interposing the inner space (A) of the organic light emitting display 500 therebetween. As described in FIG. 1, the metal oxide layer 410 is formed by oxidation of a metal layer combining with humidity or gas contained in the inner space (A) of the organic light emitting display 500. As a result, humidity or gas contained in the inner space (A) may be removed by the metal oxide layer 410. In addition, the metal oxide layer 410 formed by oxidation of the metal layer absorbs humidity, thereby removing humidity near the pixel part 210.

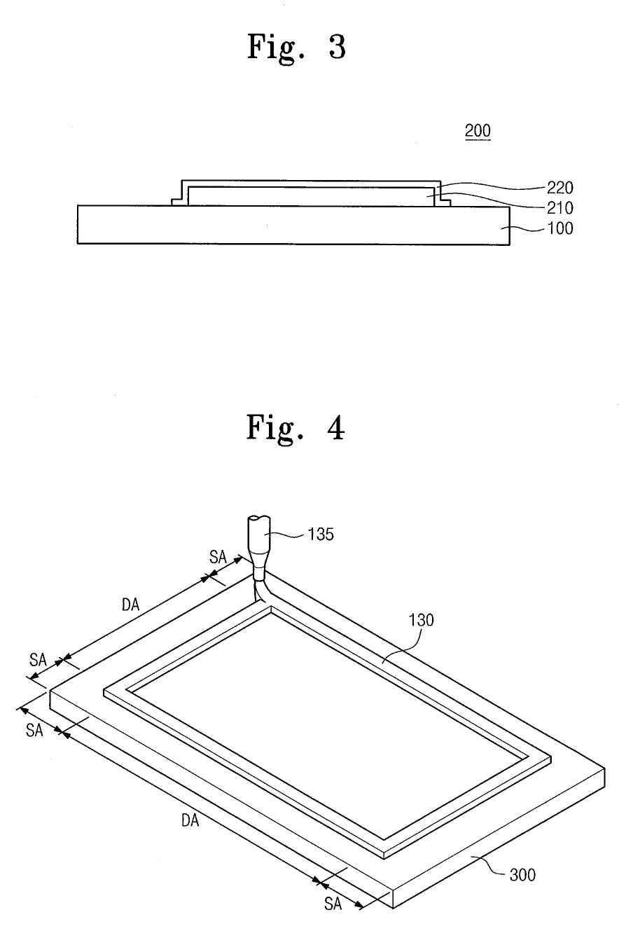

FIGS. 3 to 8 are views illustrating an exemplary embodiment of a manufacturing method of the organic light emitting display of FIG. 1. In FIGS. 3 to 8, the same reference numerals denote the same elements in FIGS. 1 and 2, and thus the detailed descriptions of the same elements will be omitted.

Referring to FIG. 3, the pixel part 210 is formed on the first base substrate 100. After forming the pixel part 210 on the first base substrate 100, the protective layer 220 is formed on the pixel part 210 to complete the array substrate 200. The protective layer 220 covers the upper portion and the side portion of the pixel part 210 to prevent humidity or gas from being absorbed into the pixel part 210 from an exterior source.

Referring to FIG. 4, the coupling member 130 is formed on the second base substrate 300 using a dispenser 135. The coupling member 130 includes the frit glass, and the coupling member 130 is formed in the peripheral area SA of the second base substrate 300 to surround the display area DA.

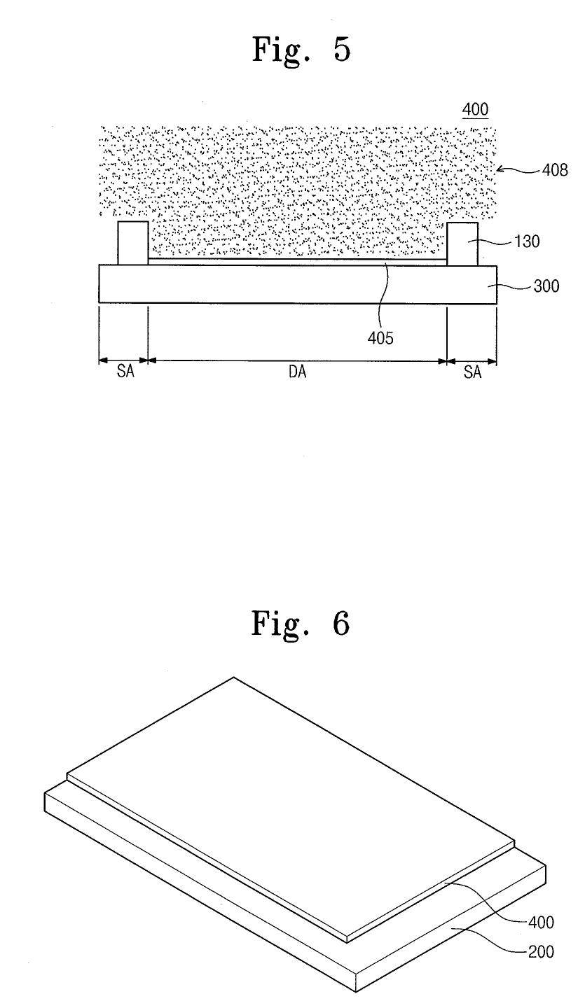

Referring to FIG. 5, a metal layer 405 is formed on the second base substrate 300 on which the coupling member 130 is formed, thereby completely forming the cover substrate 400. The metal layer 405 includes a metal material as titanium, and the metal layer 405 is formed in an area corresponding to the display area DA. Also, the metal layer 405 may be formed using a chemical vapor deposition method in which a source material 408 including titanium reacts with the second base substrate 300 to form the metal layer 405. If the metal layer 405 is formed by the chemical vapor deposition method, since the metal layer 405 is formed on an entire surface of the second base substrate 300, an additional etching process that partially etches the metal layer 405 may be performed.

In this exemplary embodiment of the present disclosure, the metal layer 405 is formed after the coupling member 130 is formed on the second base substrate 300. However, in one aspect, the coupling member 130 may be formed after the metal layer 405 is formed on the second base substrate 300.

Referring to FIG. 6, after the array substrate 200 and the cover substrate 400 are completely formed, the array substrate 200 is coupled with the cover substrate 400 to face the cover substrate 400. Although not shown in FIG. 6, the coupling member 130 (shown in FIG. 4) is interposed between the array substrate 200 and the cover substrate 400.

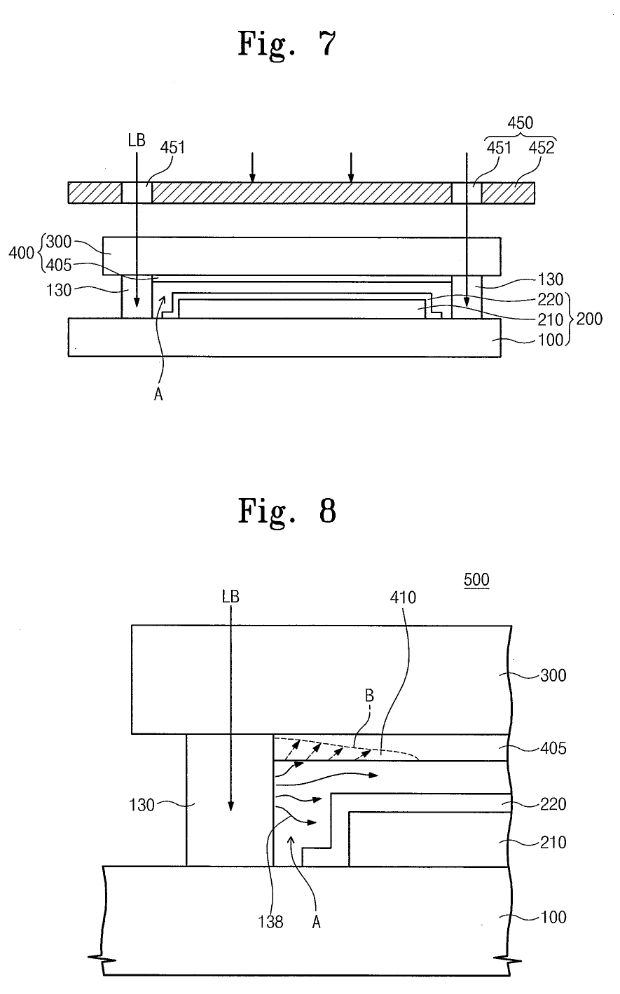

Referring to FIGS. 7 and 8, after the array substrate 200 is coupled with the cover substrate 400 to face the cover substrate 400, a mask 450 is placed above the cover 400, and a laser beam LB is irradiated from an upper position of the mask 450 onto the coupling member 130 through the mask 450 during a predetermined period.

The mask 450, in one embodiment, includes a transmission region 451 and a non-transmission region 452. The laser beam LB transmits the transmission region 451, and the laser beam LB may be irradiated onto the coupling member 130 through the transmission region 451 because the transmission region 451 is arranged to face the coupling member 130.

In one aspect, the non-transmission region 452 blocks the laser beam LB, and the non-transmission region 452 is arranged to face the pixel part 210. Thus, the laser beam LB is blocked by the non-transmission region 452 and the laser beam LB is not irradiated onto the pixel part 210.

In one implementation, when irradiating the laser beam LB onto the coupling member 130 during the predetermined period, the coupling member 130 is melted and then hardened. Therefore, the first base substrate 100 and the second base substrate 300 are firmly coupled with each other by the coupling member 130.

In one aspect, when the laser beam LB is irradiated onto the coupling member 130, heat of about 600° C. to about 1000° C. is provided to the coupling member 130 in order to melt the coupling member 130 including the frit glass. While the coupling member 130 is heated, gas 138 may be generated from the coupling member 130, and the gas 138 moves to the inner space (A) of the organic light emitting display 500.

In one aspect, the gas 138 that moves within the inner space (A) may react with the pixel part 210 and deteriorate the light emitting function of the pixel part 210. However, if the gas 138 includes oxygen, the gas 138 may oxidize the metal layer 405, to thereby form the metal oxide layer 410. As a result, oxygen that is generated and contained in the inner space (A) may be removed by the oxidization of the metal layer 405.

In another aspect, since the metal oxide layer 410 formed by oxidation of the metal layer 405 may absorb humidity, humidity contained in the inner space (A) may be removed by the metal oxide layer 410. As such, oxygen contained in the gas 138is dispersed in the metal layer 405, so that the metal layer 405 is gradually oxidized by the dispersed oxygen, thereby forming the metal oxide layer 410. That is, the metal layer 405 and the metal oxide layer 410 may be divided according to a border line B, and volumes of the metal layer 405 and the metal oxide layer 410 may be varied according to a degree of oxidation of the metal layer 405.

In this exemplary embodiment of the present disclosure, when the laser beam LB is irradiated onto the coupling member 130, the mask 450 is used so that the laser beam LB may be irradiated only onto the coupling member 130. This is because an amount of gas generated by the laser beam LB that is irradiated onto an area where the coupling member 130 is not formed may be minimized. However, as described above, in case that gas generated by the laser beam LB that is irradiated onto the coupling member 130 is removed by the oxidation of the metal layer 405, the laser beam LB may be directly irradiated onto the coupling member 130 without using the mask 450.

According to the above, in one embodiment, the metal layer is formed on the second substrate that faces the first substrate on which the pixel part is arranged. Since the metal layer is combined with humidity and gas near the pixel part and is oxidized, the oxygen near the pixel part may be removed. So, the light emitting function of the pixel part may be prevented from being deteriorated by humidity and gas, thereby improving reliability and lifecycle of the organic light emitting display.

Although various exemplary embodiments of the present disclosure have been described herein, it is understood that the present disclosure should not be limited to these various exemplary embodiments but various changes and modifications may be made by one of ordinary skilled in the art within the spirit and scope of the present disclosure, as hereinafter claimed.

What is claimed is:

1. A method of manufacturing an organic light emitting display, the method comprising:
forming a pixel part on a first substrate;
forming a metal layer on a second substrate;
forming a coupling member on the first substrate or on the second substrate; and
coupling the first substrate and the second substrate with the coupling member.

2. The method of claim 1, wherein the metal layer comprises titanium.

3. The method of claim 1, wherein the coupling member comprises a frit.

4. The method of claim 3, wherein the first substrate and the second substrate are coupled by irradiating a laser beam on the coupling member.

5. The method of claim 4, further comprising forming a metal oxide layer when the metal layer combines with oxygen generated when the laser is irradiated onto the coupling member.

6. The method of claim 5, further comprising absorbing humidity with the metal oxide layer to prevent the humidity from being applied to the pixel part.

7. The method of claim 1, wherein the forming of the pixel part comprises:
forming one or more thin film transistors on the first substrate; and
forming organic light emitting layers adapted to generate the light in response to turn-on operations of the thin film transistors.

8. The method of claim 7, wherein the light exits to an exterior of the display through the first substrate.

9. The method of claim 1, further comprising forming a protective layer at an uppermost position of the first substrate to cover the pixel part.

10. The method of claim 1, wherein, after the first substrate and the second substrate are coupled with each other by the coupling member, the metal layer faces the pixel part, and the metal layer and the pixel part are surrounded by the coupling member.

11. An organic light emitting display comprising:
a first substrate;
a pixel part arranged on the first substrate;
a second substrate facing the first substrate;
a coupling member interposed between the first substrate and the second substrate to couple the first substrate and the second substrate; and
a metal oxide layer on the second substrate.

12. The organic light emitting display of claim 11, wherein the metal oxide layer comprises titanium-dioxide.

13. The organic light emitting display of claim 12, wherein the metal oxide layer absorbs humidity to inhibit the humidity from being applied to the pixel part.

14. The organic light emitting display of claim 11, wherein the coupling member comprises a frit.

15. The organic light emitting display of claim 11, wherein the pixel part comprises:
one or more thin film transistors; and
organic light emitting layers adapted to generate the light in response to turn-on operations of thin film transistors.

16. The organic light emitting display of claim 15, wherein the light exits to an exterior of the display through the first substrate.

17. The organic light emitting display of claim 11, further comprises a protective layer arranged at an uppermost position of the first substrate to cover the pixel part.

18. The organic light emitting display of claim 11, wherein the metal layer faces the pixel part, and wherein the metal layer and the pixel part are surrounded by the coupling member.
